(19) United States
(12) Patent Application Publication
(10) Pub. No.: US 2024/0203777 A1
(43) Pub. Date: Jun. 20, 2024

(54) APPARATUS FOR TREATING SUBSTRATE

(71) Applicant: SEMES CO., LTD., Cheonan-si (KR)

(72) Inventors: In Ki JUNG, Hwaseong-si (KR); Jeong Hyup YU, Hwaseong-si (KR); Young Joon HAN, Cheonan-si (KR); Sung Bum PARK, Cheonan-si (KR); Sung Wook BAE, Cheonan-si (KR)

(73) Assignee: SEMES CO., LTD., Cheonan-si (KR)

(21) Appl. No.: 18/545,660

(22) Filed: Dec. 19, 2023

(30) Foreign Application Priority Data
Dec. 20, 2022 (KR) 10-2022-0179662

(51) Int. Cl. H01L 21/68

(52) U.S. Cl. CPC H01L 21/68; H01L 21/6708

(57) ABSTRACT

The inventive concept provides a substrate treating apparatus. The substrate treating apparatus includes a chuck supporting a substrate; a liquid supply unit configured to supply a liquid to a substrate supported on the chuck; a treating container surrounding the substrate supported on the chuck; and an eccentricity correction unit configured to correct an eccentricity of the substrate supported on the chuck, and wherein the eccentricity correction unit contacts a plurality of points on a side end of the substrate supported on the chuck to match a center of the substrate with a center of the chuck.

### CROSS-REFERENCE TO RELATED APPLICATIONS

A claim for priority under 35 U.S.C. § 119 is made to Korean Patent Application No. 10-2022-0179662 filed on Dec. 20, 2022, in the Korean Intellectual Property Office, the entire contents of which are hereby incorporated by reference.

### BACKGROUND

Embodiments of the inventive concept described herein relate to a substrate treating apparatus and a substrate treating method, more specifically, a substrate treating apparatus and a substrate treating method for correcting a position of a substrate.

In general, in order to manufacture a semiconductor element, various processes such as a photo process, an etching process, an ion implantation process, and a deposition process are performed. In each process, a liquid is supplied onto a substrate to perform a predetermined treatment.

In the various processes of treating the substrate, the substrate must be mounted in a correct position on a support unit. For example, in a liquid treatment process of supplying a liquid to the substrate, if the substrate is mounted in a position which deviates from the correct position on the support unit, an impact point of the liquid supplied on the substrate deviates. In this case, the liquid is not uniformly coated on the substrate, or the liquid is not targeted at a specific point on the substrate to be accurately supplied, which hinders a uniform liquid treatment of the substrate. In addition, if the substrate is mounted in a position which deviates from the correction position on the support unit in a process of treating the substrate using a plasma, a sheath of the plasma formed on a top side of the substrate changes, hindering a uniform plasma treatment of the substrate. In particular, it is difficult to uniformly etch an edge region of the substrate if the substrate is not mounted in the correct position on the support unit in a process of etching a thin film or foreign substances formed on the edge region of the substrate. This acts as a factor causing a decrease in a yield of treated substrates.

### SUMMARY

Embodiments of the inventive concept provide a substrate treating apparatus and a substrate treating method for uniformly treating a substrate.

Embodiments of the inventive concept provide a substrate treating apparatus and a substrate treating method for seating a substrate on a support unit in a correct position to uniformly etch an edge region of the substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chuck supporting a substrate; a liquid supply unit configured to supply a liquid to a substrate supported on the chuck; a treating container surrounding the substrate supported on the chuck; and an eccentricity correction unit configured to correct an eccentricity of the substrate supported on the chuck, and wherein the eccentricity correction unit contacts a plurality of points on a side end of the substrate supported on the chuck to match a center of the substrate with a center of the chuck.

In an embodiment, the eccentricity correction unit includes: a first correction part configured to contact each of a first point and a second point among the points, sharing any one axis on a horizontal plane; and a second correction part configured to contact a third point included in another axis which is different from the any one axis.

In an embodiment, the first correction part includes a 1-1 correction unit and a 1-2 correction unit, and wherein the 1-1 correction unit includes: a 1-1 contact part configured to contact the first point; and a 1-1 driving unit configured to change a position of the 1-1 contact part, and wherein the 1-2 correction unit includes: a 1-2 contact part configured to contact the second point; and a 1-2 driving unit configured to change a position of the 1-2 contact part.

In an embodiment, the 1-1 driving unit and the 1-2 driving unit move the 1-1 contact part and the 1-2 contact part, respectively, on the axis including the first point and the second point.

In an embodiment, the second correction part moves on an axis which is perpendicular to the axis on which the 1-1 contact part and the 1-2 contact part moves at a horizontal plane.

In an embodiment, the second correction part includes: a second contact unit configured to contact the third point; a second driving unit configured to change a position of the second contact unit; and an elastic part configured to provide an elastic force in a moving direction of the second contact unit.

In an embodiment, the second driving unit moves along a guide rail formed on a top surface of a body, the second contact unit is coupled to a surface of the second driving unit, an other surface of the second driving unit facing the surface faces the body, an end of the elastic part is coupled to the other surface, and an other end of the elastic part is coupled the body facing the other surface.

In an embodiment, the second correction part further includes a displacement measurement part configured to measure a displacement of the substrate based on a displacement of the second driving unit by the elastic force of the elastic part.

In an embodiment, the displacement measurement part measures the displacement of the second driving unit with respect to different points of the substrate by rotating the chuck while the second contact unit is supporting the side end of the substrate, in a state in which the second driving unit is not driven.

In an embodiment, the substrate treating apparatus further includes a housing having an inner space, and wherein the eccentricity correction unit is installed at a sidewall of the housing.

In an embodiment, the first correction part moves in a direction parallel to the any one axis, and moves in a direction perpendicular to the any one axis on a horizontal plane, and the second correction part moves in a direction perpendicular to the any one axis at a horizontal plane.

The inventive concept provides a substrate treating method. The substrate treating method includes mounting a substrate to be treated on a chuck; measuring an eccentricity of a substrate mounted on the chuck; correcting the eccentricity of the substrate based on an eccentricity degree of the substrate measured at the measuring the eccentricity of the substrate; and treating a substrate with its eccentricity corrected, and wherein at the correcting the eccentricity of the substrate, a center of the substrate to be treated is matched within an error range of a center of the chuck, by contacting a plurality of points among a side end of the substrate supported on the chuck.

In an embodiment, at the measuring the eccentricity of the substrate, a first correction part contacts each of a first point and a second point among the points, which share any one axis on a horizontal plane, and a second correction part contacts a third point included in another axis which is different from the any one axis to move a substrate mounted on the chuck to a predetermined reference position.

In an embodiment, the first correction part includes a 1-1 correction unit contacting the first point, and a 1-2 correction unit contacting the second point, and wherein at the measuring the eccentricity of the substrate, after the substrate is moved to the reference position, the second correction part supports a side end of the substrate to rotate the chuck to measure a displacement from an elastic force of the second correction part with respect to different points of the substrate, to measure the eccentricity of the substrate based on the displacement of the second correction part which is measured.

In an embodiment, at the correcting the eccentricity of the substrate, the 1-1 correction unit and the 1-2 correction unit move in a direction toward each other, and the second correction part corrects the eccentricity of the substrate by moving in a downward direction.

In an embodiment, at the correcting the eccentricity of the substrate, the 1-1 correction unit and the 1-2 correction unit move in a direction away from each other, and the second correction part corrects the eccentricity of the substrate by moving in an upward direction.

In an embodiment, at the correcting the eccentricity of the substrate, the 1-1 correction unit and the 1-2 correction unit each move along any one axis on the horizontal plane, and the second correction part moves along an axis perpendicular to the any one axis on the horizontal plane, to correct the eccentricity of the substrate.

In an embodiment, the substrate treating method further includes checking the eccentricity of measuring a displacement with respect to different points of the substrate by rotating the substrate having its eccentricity corrected at the correcting the eccentricity of the substrate, and checking whether the eccentricity degree of the substrate based on the displacement which is measured is within the error range.

In an embodiment, at the treating the substrate a treatment of etching an edge region of the substrate is performed.

The inventive concept provides a substrate treating apparatus. The substrate treating apparatus includes a housing having an inner space; a chuck positioned in the inner space and supporting and rotating a substrate; a liquid supply unit configured to supply a liquid to a substrate supported on the chuck to etch an etch region of the substrate; a treating container surrounding the substrate supported on the chuck; a lifting/lowering unit configured to lift and lower the treating container; and an eccentricity correction unit configured to contact a plurality of points among a side end of the substrate supported on the chuck, to correct an eccentricity of the substrate supported on the chuck, and wherein the eccentricity correction unit includes: a first correction part configured to contact each of any one point and any other point among the points, sharing any one axis on a horizontal plane; and a second correction part configured to another point included in an axis different from the any one axis, and wherein the second correction part includes: a displacement measurement part configured to measure a displacement degree with respect to different points of a rotating substrate; and an elastic part configured to provide an elastic force by contacting the side end of the substrate.

According to an embodiment of the inventive concept, a substrate may be uniformly treated.

According to an embodiment of the inventive concept, a substrate may be mounted on a support unit in a correction position so an edge region of the substrate may be uniformly etched.

According to an embodiment of the inventive concept, an eccentricity of a substrate to be treated may be accurately measured and corrected.

According to an embodiment of the inventive concept, substrates having different sizes or substrates treated in different environments according to a recipe may each have their eccentricity accurately corrected.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a cross-sectional view schematically illustrating a process chamber according to an embodiment.

FIG. 3 is a cross-sectional view of the process chamber in which an eccentricity correction unit is installed according to an embodiment, viewed from above.

FIG. 4 is a perspective view schematically illustrating a second correction part according to an embodiment.

FIG. 5 is a cross-sectional view schematically illustrating the second correction part according to an embodiment, viewed from a side.

FIG. 6 is a flowchart of a substrate treating method according to an embodiment.

FIG. 7 is a partial enlarged view of the process chamber performing a preparation step according to an embodiment.

FIG. 8 to FIG. 12 sequentially illustrate a process of performing an eccentricity measurement step according to an embodiment.

FIG. 13 schematically illustrates performing an eccentricity correction step according to an embodiment.

FIG. 14 schematically illustrates performing an eccentricity inspection step according to an embodiment.

FIG. 15 is a cross-sectional view of the eccentricity correction unit installed in the process chamber according to another embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

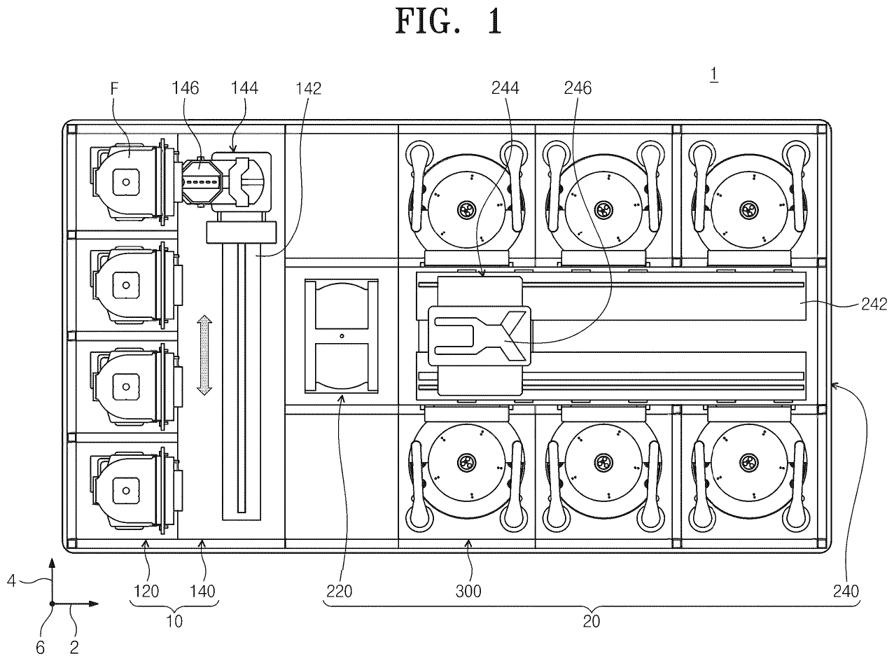

FIG. 1 is a cross-sectional view schematically illustrating a substrate treating apparatus according to an embodiment.

Referring to FIG. 1, the substrate treating apparatus 1 includes an index module 10 and a treating module 20. According to an embodiment, the index module 10 and the treating module 20 are disposed in a direction.

Hereinafter, a direction in which the index module 10 and the treating module 20 are disposed is defined as a first direction 2. In addition, when viewed from above, a direction perpendicular to the first direction 2 is defined as a second direction 4, and a direction perpendicular to a plane including both the first direction 2 and the second direction 4 is defined as a third direction 6. For example, the third direction 6 may be a direction perpendicular to the ground. In addition, hereinafter, the first direction 2 may be defined as an X-axis. In addition, the second direction 4 may be defined as a Y-axis. However, this is only for convenience of understanding, and the second direction 4 may be an X-axis, and the first direction 2 may be a Y-axis.

The index module 10 transfers the substrate between a container F and the treating module 20. The index module 10 transfers a substrate treated by the treating module 20 to the container F. In addition, the index module 10 transfers a substrate scheduled for a predetermined treatment in the container F to the treating module 20. The index module 10 has a lengthwise direction parallel to the second direction 4. The index module 10 has a load port 120 and an index frame 140.

The container F in which the substrate is stored is mounted on the load port 120. The load port 120 is positioned on an opposite side of the treating module 20 based on the index frame 140. In addition, a plurality of load ports 120 may be provided. The plurality of load ports 120 may be in a row along the second direction 4. The number of load ports 120 may increase or decrease according to a process efficiency and a footprint condition of the treating module 20.

A plurality of slots (not shown) for storing the substrate are formed within the container F. As the container F, a sealed container such as a front opening unified pod (FOUP) may be used. The container F may be placed in the load port 120 by a transfer means (not shown) such as an overhead transfer, an overhead conveyor, or an automatic guided vehicle.

An index rail 142 and an index robot 144 are disposed within the index frame 140. The index rail 142 has a lengthwise direction parallel to the second direction 4. The index robot 144 transfers the substrate. The index robot 144 transfers the substrate between the container F and a buffer unit 220 to be described later. The index robot 144 is disposed on the index rail 142 to forwardly and backwardly move along the lengthwise direction of the index rail 142.

The index robot 144 has an index hand 146. The substrate may be placed on the index hand 146. The index hand 146 rotates around the third direction 6 and upwardly and downwardly moves along the third direction 6. A plurality of index hands 146 may be provided. The plurality of index hands 146 may be spaced apart from each other in a vertical direction. The plurality of index hands 146 may be forwardly and backwardly moved, and rotated independently of each other.

The treating module 20 includes a buffer unit 220, a transfer frame 240, and a process chamber 300.

The buffer unit 220 provides a space in which the substrate temporarily remains. More specifically, the buffer unit 220 provides a space at which a substrate taken in from the treating module 20 and a substrate taken out from the treating module 20 stay temporarily. The buffer unit 220 is disposed between the index frame 140 and the transfer frame 240 to be described later. That is, the index frame 140, the buffer unit 220, and the transfer frame 240 are sequentially disposed along the first direction 2.

A plurality of slots (not shown) on which the substrate is mounted are disposed within the buffer unit 220. A front face and a rear face of the buffer unit 220 are opened. The front face is a surface facing the index frame 140, and the rear face is a surface facing the transfer frame 240. The index robot 144 accesses the buffer unit 220 through the front face, and the transfer robot 244 described later accesses the buffer unit 220 through the rear face.

The transfer frame 240 provides a space for transferring the substrate between the buffer unit 220 and the process chamber 300. In addition, the transfer frame 240 provides a space for transferring the substrate between a plurality of process chambers 300.

The transfer frame 240 has a lengthwise direction parallel to the first direction 2. The plurality of process chambers 300 may be disposed on both sides of the transfer frame 240. The transfer frame 240 and the process chamber 300 are disposed along the second direction 4.

A transfer rail 242 and a transfer robot 244 are disposed within the transfer frame 240. The transfer rail 242 has a lengthwise direction parallel to a lengthwise direction of the transfer frame 240. The transfer robot 244 is disposed on the transfer rail 242. The transfer robot 244 moves linearly along the lengthwise direction of the transfer rail 242 on the transfer rail 242. The transfer robot 244 transfers the substrate between the buffer unit 220 and the process chamber 300 or between the process chambers 300. The transfer robot 244 has a transfer hand 246 for transferring the substrate. Since a structure of the transfer hand 246 is mostly the same as or similar to a structure of the index hand 146 described above, a redundant description thereof will be omitted.

The plurality of process chambers 300 may be provided. As described above, the process chambers 300 may be disposed on both sides of the transfer frame 240. In addition, the process chambers 300 may be arranged in an array of A×B (A, B are natural numbers greater than 1 or 1 respectively) along the first direction 2 and the third direction 6 on a side of the transfer frame 240. Here, A may be the number of process chambers 300 in a direction along the first direction 2, and B may be the number of process chambers 300 in a direction along the third direction 6. For example, if four or six process chambers 300 are disposed on a side of the transfer frame 240, the process chambers 300 may be placed in an arrangement of 2×2 or 3×2. The above-described examples are only for convenience of understanding, and the number and arrangement of the process chambers 300 may be variously changed. In addition, unlike the above-described example, the process chambers 300 may be disposed only on a side of the transfer frame 240. In addition, the process chambers 300 may be disposed in a single layer on a side or both sides of the transfer frame 240.

In the process chamber 300, a liquid treatment process of treating the substrate by supplying a liquid to the substrate may be performed. According to an embodiment, the process chamber 300 may perform a process of removing (or etching) a thin film formed in an edge region of the substrate or foreign substances attached to the edge region of the substrate by supplying the liquid to the substrate. In addition, a chemical treatment, a rinsing treatment, and a drying treatment of the substrate may all be performed in the process chamber 300. Unlike the above description, the process chamber for drying the substrate may be provided separately from the process chamber for liquid treating the substrate by supplying a liquid. In addition, the process chamber 300 may have a different structure depending on a type of process for treating the substrate, a type of liquid supplied to the substrate, or a composition ratio of a liquid supplied to the substrate. Unlike this, the process chambers 300 may have a same or similar structure.

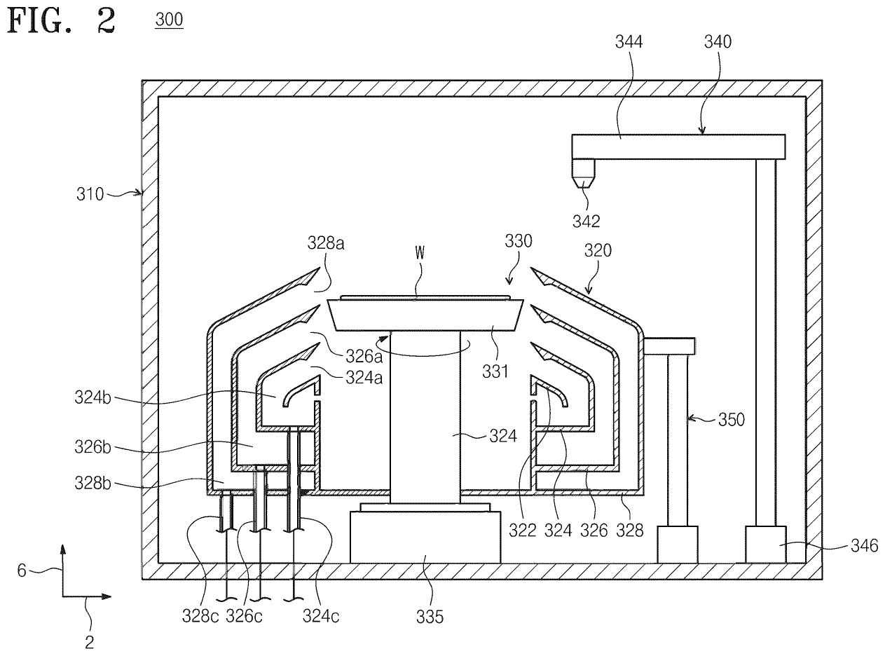

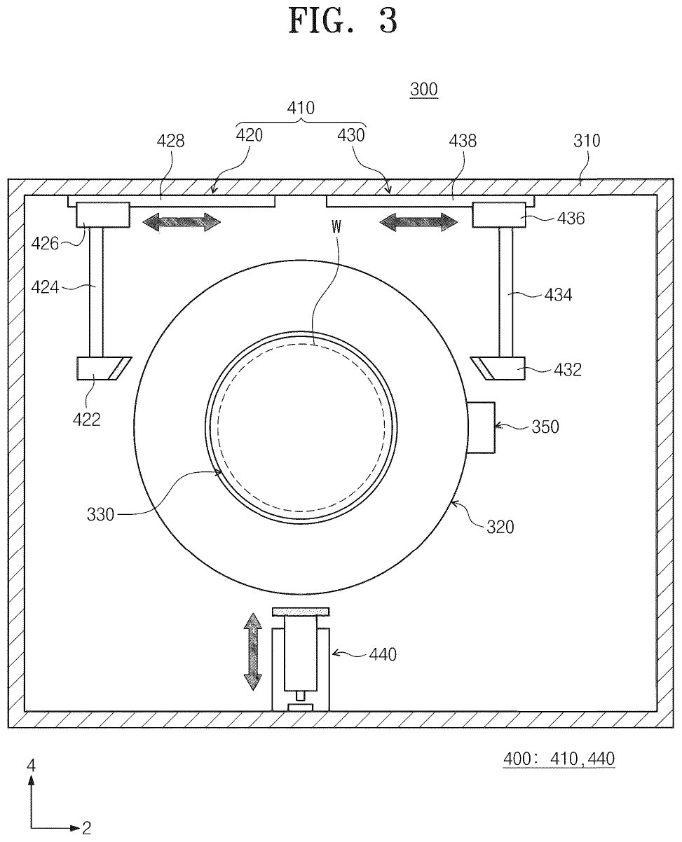

FIG. 2 is a cross-sectional view schematically illustrating the process chamber according to an embodiment. FIG. 3 is a cross-sectional view of the process chamber in which an eccentricity correction unit is installed according to an embodiment, viewed from above.

The process chamber 300 may include a housing 310, a treating container 320, a support unit 330, a liquid supply unit 340, a lifting/lowering unit 350, and an eccentricity correction unit 400.

In FIG. 2, an illustration of the eccentricity correction unit 400 according to an embodiment is omitted for convenience of understanding, and in FIG. 3, an illustration of the liquid supply unit 340 according to an embodiment is omitted for convenience of understanding. In the following, the housing 310, the treating container 320, the support unit 330, the liquid supply unit 340, and lifting/lowering unit 350 according to an embodiment will be described with reference to FIG. 2, and the eccentricity correction unit 400 according to an embodiment will be described with reference to FIG. 3.

The housing 310 may have a substantially rectangular parallelepiped shape. The housing 310 has an inner space. In the inner space, the treating container 320, the support unit 330, the liquid supply unit 340, the lifting/lowering unit 350, and the eccentricity correction unit 400, (see FIG. 3) are disposed. An inlet (not shown) is formed on a sidewall of the housing 310. The inlet (not shown) functions as a passage through which the substrate W is taken in or taken out. Although not shown, an exhaust hole for exhausting an atmosphere of the inner space is formed at a bottom of the housing 310.

The treating container 320 may be a bowl having an open top part. An inside of the treating container 320 functions as a space in which the substrate W is treated. The treating container 320 is disposed to surround the substrate W outside the substrate W supported by the support unit 330 to be described later.

According to an embodiment, the treating container 320 may include a guide wall 322 and a plurality of recollecting containers 324, 326, and 328. Each of the guide wall 322 and the recollecting containers 324, 326, and 328 has a ring shape surrounding the support unit 330. Each recollecting container 324, 326, 328 has a recollecting space 324b, 326b, 328b which separates and recollects different liquids among liquids used in a treatment of the substrate W. If a process of etching the edge region of the substrate W by supplying the liquid to the substrate W is performed, a liquid scattered by a rotation of the substrate W flows into an above-described recollecting space 324b, 326b, and 328b through inlets 324a, 326a, and 328a of each of the recollecting containers 324, 326, 328.

According to an embodiment, the treating container 320 may include a first recollecting container 324, a second recollecting container 326, and a third recollecting container 328. The first recollecting container 324 is disposed to surround the support unit 330, the second recollecting container 326 is disposed to surround the first recollecting container 324, and the third recollecting container 328 is disposed to surround the second recollecting container 326. The first inlet 324a which flows a liquid into the recollecting space 324b of the first recollecting container 324 is positioned below the second inlet 326a which flows a liquid into the recollecting space 326b of the second recollecting container 326. In addition, the second inlet 326a is positioned below the third inlet 328a which flows a liquid into the recollecting space 328b of the third recollecting container 328. Each of the recollecting containers 324, 326, and 328 are respectively coupled to liquid discharge pipes 324c, 326c, and 328c for discharging a liquid. The liquid discharged through the liquid discharge pipes 324c, 326c, and 328c may be reused using an outer regeneration system (not shown).

The number of the above-described recollecting containers may be variously changed according to the number of liquids used and the number of liquids to be recollected or discarded. Although not shown, a fume and an exhaust line for exhausting a gas may be connected to a bottom of the treating container 320.

The support unit 330 supports and rotates the substrate W. The support unit 330 may include a chuck 331 and a spin axis 334. A top surface of the chuck 331 may have a substantially circular shape. In addition, the top surface of the chuck 331 may have a diameter larger than that of the substrate W. The substrate W may be mounted on the top surface of the chuck 331. Accordingly, the chuck 331 may support the substrate W. The chuck 331 may mechanically support the substrate W using a support pin or the like, which is not shown. However, the inventive concept is not limited thereto, and the chuck 331 may support the substrate W using a vacuum adsorption method.

The spin axis 334 has a lengthwise direction parallel to the third direction 6. An end of the spin axis 334 is coupled to the chuck 331, and the other end is coupled to the shaft driver 335. More specifically, an end of the spin axis 334 is combined with a bottom end of the chuck 331, and the other end of the spin axis 334 is inserted into a hollow formed in a center of the bottom of the treating container 320 to be combined with the shaft driver 335. The shaft driver 335 rotates the spin axis 334 with a lengthwise direction of the spin axis 334 as the rotation axis. Accordingly, the chuck 331 coupled to the spin axis 334 also rotates, and the substrate W mounted on the top surface of the chuck 331 also rotates. The shaft driver 335 may be any one of known motors which transmit a rotational force. In addition, the shaft driver 335 may lift/lower the spin axis 334 in a direction parallel to the third direction 6.

The liquid supply unit 340 supplies a liquid to the substrate W supported by the support unit 330. The liquid supply unit 340 may include a nozzle 342. The liquid according to an embodiment may be a thin film formed on the substrate W or an etchant for removing foreign substances. In addition, the liquid according to an embodiment may be the thin film formed on the substrate W or an etching obstruction liquid which dilutes the liquid which removes foreign substances. According to an embodiment, the etchant may include an acid such as a hydrofluoric acid (HF) or a phosphoric acid (P₂O₅). According to an embodiment, the etching obstruction liquid may be a pure water. However, the inventive concept is not limited thereto, and the liquid according to an embodiment includes various types of liquid not shown above. That is, the liquid according to an embodiment includes all of various types of liquid used to treat the substrate W. The nozzle 342 is coupled to an arm 344. Accordingly, the nozzle 342 is supported by the arm 344. The arm 344 may have a substantially upside-down ‘L’ shape. The arm 344 is coupled to an arm driver 346. The arm driver 346 may swing or linearly move the arm 344. Accordingly, the nozzle 342 may be moved between a standby position and a liquid supply position by the arm driver 346.

The standby position may be a position at which the nozzle 342 stands-by when a liquid is not supplied onto the substrate W. The liquid supply position may be a position at which the nozzle 342 supplies the liquid onto the substrate W. For example, when viewed from above, the nozzle 342 may be positioned to overlap the substrate W at the liquid supply position. More specifically, when supplying an etchant on the substrate W, the nozzle 342 may be positioned to correspond to a top side of the edge region of the substrate W. In addition, when supplying an etching obstruction liquid on the substrate W, the nozzle 342 may be positioned corresponding to a top side of a central region of the substrate W.

Unlike shown in FIG. 2, a plurality of nozzles 342 may be provided. Some of the plurality of nozzles 342 may supply the above-described etchant to the substrate W. Another portion of the plurality of nozzles 342 may supply the etching obstruction liquid described above to the substrate W. In addition, yet another portion of the plurality of nozzles 342 may supply an etchant mixed at different composition ratios to the substrate W. In addition, the plurality of nozzles 342 are each combined to different arms, and each arm can be combined independently to different arm drivers. Accordingly, positions of each of the plurality of nozzles 342 may be changed individually.

The lifting/lowering unit 350 changes the position of the treating container 320. For example, the lifting/lowering unit 350 lifts the treating container 320 in a direction parallel to the third direction 6. The lifting/lowering unit 350 may be any one of known motors which transmit a driving force. A relative height between the treating container 320 and the substrate W supported by the support unit 330 is changed by an up/down movement of the treating container 320. Accordingly, the recollecting containers 324, 326, and 328 may separate and recollect a liquid according to a type and a composition ratio of the liquid supplied to the substrate W.

According to an embodiment, when treating the substrate W, the lifting/lowering unit 350 may upwardly move the treating container 320 so that a top end of the treating container 320 is higher than a top end of the substrate W. In addition, when correcting an eccentricity of the substrate W after the substrate W is treated or before the substrate W is treated, the lifting/lowering unit 350 may downwardly move the treating container 320 so that the top end of the treating container 320 is lower than a top end of the chuck 331.

The eccentricity correction unit 400 changes the position of the substrate W mounted on the chuck 331. More specifically, the eccentricity correction unit 400 corrects the eccentricity of the substrate W so that the center of the substrate W mounted on the chuck 331 matches a central axis of the chuck 331. The eccentricity correction unit 400 according to an embodiment is in contact with a side end of the substrate W to change the position of the substrate W. A detailed mechanism for this will be described later.

The eccentricity correction unit 400 may include a first correction part 410 and a second correction part 440. The first correction part 410 and the second correction part 440 may be installed on sidewalls of the housing 310, respectively. More specifically, the first correction part 410 may be installed on a side wall of the housing 310, and the second correction part 440 may be installed on the other side wall facing the side wall of the housing 310 at which the first correction part 410 is installed. However, the inventive concept is not limited to this, and installation positions of the first correction part 410 and the second correction part 440 can be variously changed on the sidewalls of the housing 310.

The first correction part 410 contacts a plurality of points on the side end of the substrate W to change the position of the substrate W and determine the position of the substrate W. According to an embodiment, the first correction part 410 changes the position of the substrate W by contacting two different points on the same axis when viewed from above. For example, two different points on the side end of the substrate W in contact with the first correction part 410 may be positioned on the X-axis. That is, two different points on the side end of the substrate W in contact with the first correction part 410 may share the X-axis on the horizontal plane.

The first correction part 410 may include a 1-1 correction unit 420 and a 1-2 correction unit 430.

The 1-1 correction unit 420 may include a 1-1 contact part 422, a 1-1 arm 424, a 1-1 driving unit 426, and a 1-1 rail 428.

The 1-1 contact part 422 is in contact with a first point on the side end of the substrate W to change the position of the substrate W. A surface of the 1-1 contact part 422 may be formed to be inclined. An inclined surface of the 1-1 contact part 422 may be a surface in contact with the substrate W. More specifically, the inclined surface of the 1-1 contact part 422 may be inclined at an angle corresponding to an angle formed by a tangential direction of the substrate W. In addition, the inclined surface of the 1-1 contact part 422 may be made of a material such as a carbon-filled Poly-Ether-Ether-Ketone (PEEK). However, the inventive concept is not limited thereto, and an entire region of the 1-1 contact part 422 may be made of a material such as a PEEK.

The 1-1 arm 424 is coupled to the 1-1 contact part 422. The 1-1 arm 424 may have a lengthwise direction parallel to the second direction 4. The 1-1 contact part 422 is coupled to an end of the 1-1 arm 424, and the 1-1 driving unit 426 is coupled to the other end of the 1-1 arm 424. The 1-1 driving unit 426 may be any one of known linear motors which provide a driving force to change the position of the 1-1 arm 424. In addition, the 1-1 rail 428 may be installed on a sidewall of the housing 310. The 1-1 rail 428 has a lengthwise direction parallel to the first direction 2. The 1-1 driving unit 426 is mounted on the 1-1 rail 428 and moves in the lengthwise direction of the 1-1 rail 428 (e.g., in the first direction 2). Accordingly, the 1-1 arm 424 and the 1-1 contact part 422 coupled to the 1-1 driving unit 426 also move along the first direction 2, and the 1-1 contact part 422 can contact the first point on the side end of the substrate W to change the position of the substrate W.

The 1-2 correction unit 430 may include a 1-2 contact part 432, a 1-2 arm 434, a 1-2 driving unit 436, and a 1-2 rail 438.

The 1-2 contact part 432 is in contact with a second point on the side end of the substrate W to change the position of the substrate W. The second point according to an embodiment may be a point sharing the same X-axis on the horizontal plane with the first point as described above.

The 1-2 contact part 432, the 1-2 arm 434, 1-2 driving unit 436, and 1-2 rail 438 are symmetrical structures when viewed above with the aforementioned 1-1 contact part 422, the 1-1 driving unit 424, and 1-1 rail 428, respectively. In other words, the 1-2 contact part 432, the 1-2 arm 434, the 1-2 driving unit 436, and the 1-2 rail 438 have the same or similar structures as the 1-1 contact part 422, the 1-1 arm 424, and the 1-1 rail 428, respectively. Accordingly, hereinafter, the 1-1 correction unit 420 will be mainly described, and a description of the 1-2 correction unit 430 will be omitted.

The components included in the 1-1 correction unit 420 and the 1-2 correction unit 430 described above may be disposed not to interfere with the liquid supply unit 340 shown in FIG. 2. In addition, the components included in the 1-1 correction unit 420 and the 1-2 correction unit 430 may be disposed in a position that does not interfere with the entrance (not shown) formed on the sidewall of the housing 310.

Unlike the above-described example, each of the 1-1 arm 424 and the 1-2 arm 434 may have a lengthwise direction parallel to the first direction 2. In this case, the 1-1 rail 428 and the 1-2 rail 438 may not be provided, and the 1-1 driving unit 426 and the 1-2 driving unit 436 may move the 1-1 arm 424 and the 1-2 arm 434 in a structure such as a cylinder, respectively, in a direction parallel to the first direction 2.

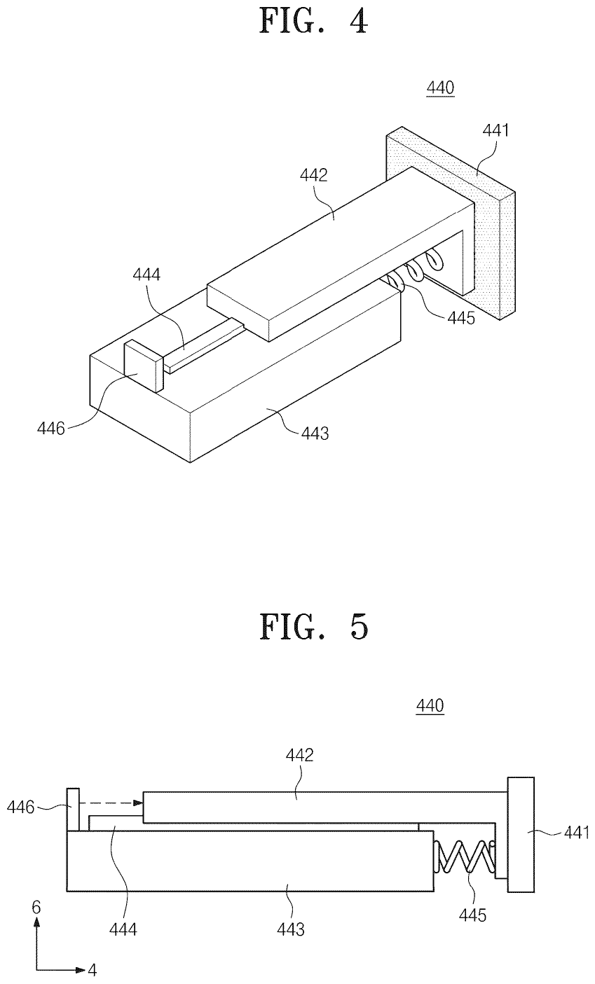

FIG. 4 is a perspective view schematically illustrating the second correction part according to an embodiment. FIG. 5 is a cross-sectional view schematically illustrating the second correction part viewed from a side according to an embodiment.

Hereinafter, the second correction part 440 according to an embodiment will be described with reference to FIG. 3 to FIG. 5.

The second correction part 440 is in contact with any one point on the side end of the substrate W to change the position of the substrate W. According to an embodiment, the second correction part 440 is in contact with any one point on the side end of the substrate W belonging to an axis in which a plurality of points at which the first correction part 410 contacts the substrate W is included, and another axis, belong to on the horizontal plane. That is, the second correction part 440 may contact a third point on the side end of the substrate W belonging to an X-axis different from the X-axis on the horizontal plane in which the first correction part 410 contacts the substrate W. For example, the third point may mean a lowest point of the substrate W when viewed from above.

The second correction part 440 may include a second contact unit 441, a second driving unit 442, a body 443, a guide rail 444, an elastic part 445, and a displacement measurement part 446.

The second contact unit 441 may be in contact with the third point on the side end of the substrate W. The second contact unit 441 may have a substantially rectangular parallelepiped shape. In addition, the second contact unit 441 may be made of a material such as a carbon-filled PEEK. The second contact unit 441 is coupled to the second driving unit 442.

The second driving unit 442 may have a substantially upside-down ‘L’ shape when viewed from the front. However, the inventive concept is not limited thereto, and the structure of the second driving unit 442 may be modified into various shapes. The second driving unit 442 changes a position of the second contact unit 441. The second driving unit 442 may be any one of known linear motors.

The body 443 may be coupled to the other sidewall of the housing 310. A guide rail 444 is formed on a top surface of the body 443. The guide rail 444 has a lengthwise direction parallel to the second direction 4. The above-described second driving unit 442 forwardly and backwardly moves on the guide rail 444. Accordingly, the second contact unit 441 coupled to the second driving unit 442 may also move along the second direction 4 to contact the third point on the side end of the substrate W.

The elastic part 445 is disposed between the other surface of the second driving unit 442 and the body 443. More specifically, an end of the elastic part 445 is coupled to the other surface of the second driving unit 442, and the other end of the elastic part 445 is coupled to the body 443 facing the other surface of the second driving unit 442. The other surface of the second driving unit 442 may be a surface facing a surface of the second driving unit 442 to which the second contact unit 441 is coupled. According to an embodiment, the elastic part 445 may include a spring having an elastic force. Accordingly, the elastic part 445 may provide the elastic force in a moving direction (e.g., the second direction 4) of the second contact unit 441. In addition, when the second correction part 440 contacts the third point on the side end of the substrate W, the elastic part 445 may be designed to have an elastic coefficient which does not cause damage to the substrate W.

The displacement measurement part 446 may measure a displacement of the second driving unit 442. The displacement measurement part 446 according to an embodiment may be a proximity sensor which oscillates a certain wavelength toward a target object and receives a wavelength reflected from the target object to measure a distance to the target object. The target object according to an embodiment may be the second driving unit 442. The displacement measurement part 446 may be disposed on a top surface of the body 443. According to an embodiment, the displacement measurement part 446 may be disposed at an end of the top surface of the body 443. A mechanism by which the displacement measurement part 446 measures the displacement of the second driving unit 442 will be described later.

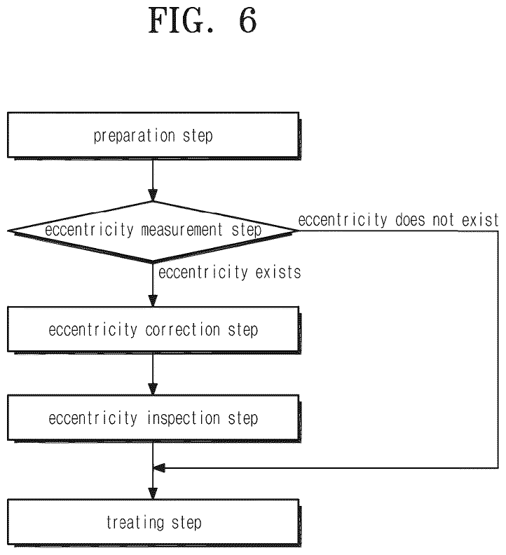

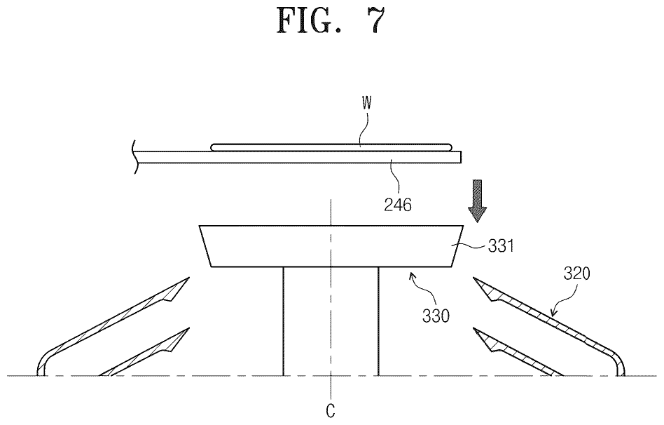

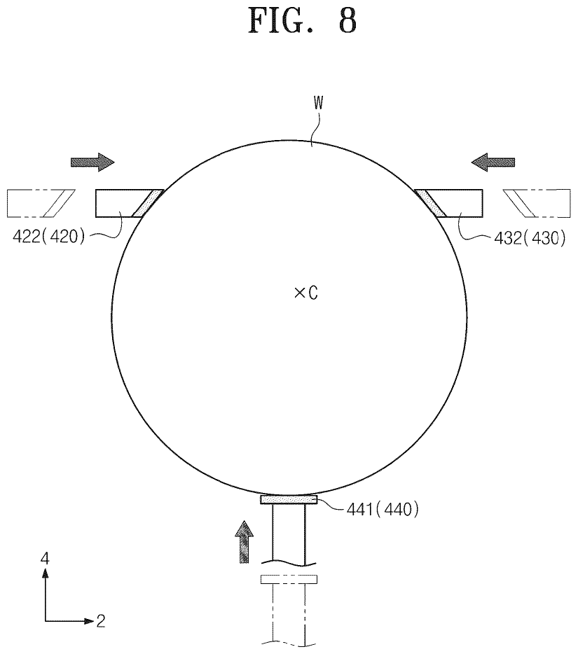

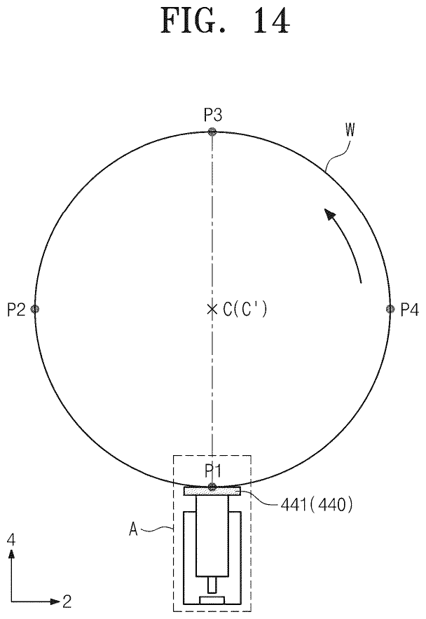

FIG. 6 is a flowchart of a substrate treating method according to an embodiment. FIG. 7 is a partial enlarged view of the process chamber performing a preparation step according to an embodiment. FIG. 8 to FIG. 12 sequentially illustrate a process of performing an eccentricity measurement step according to an embodiment. FIG. 13 schematically illustrates performing an eccentricity correction step according to an embodiment. FIG. 14 schematically illustrates performing an eccentricity inspection step according to an embodiment.

Hereinafter, a substrate treating method according to an embodiment will be described with reference to FIG. 6 to FIG. 14. The substrate treating method described below may be performed by the substrate treating apparatus described with reference to FIG. 1 to FIG. 5. Hereinafter, the substrate treating method according to an embodiment will be described by citing the reference numerals illustrated in FIG. 1 to FIG. 5. In addition, the substrate treating method described below may be performed by controlling configurations included in the substrate treating apparatus described above by a controller not shown.

The controller (not shown) may comprise a process controller consisting of a microprocessor (computer) that executes a control of the substrate treating apparatus 1, a user interface such as a keyboard via which an operator inputs commands to manage the substrate treating apparatus 1, and a display showing the operation situation of the substrate treating apparatus 1, and a memory unit storing a treating recipe, i.e., a control program to execute treating processes of the substrate treating apparatus 1 by controlling the process controller or a program to execute components of the substrate treating apparatus 1 according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The substrate treating method according to an embodiment may include a preparation step S10, an eccentricity measurement step S20, an eccentricity correction step S30, an eccentricity inspection step S40, and a treating step S50. The preparation step S10, the eccentricity measurement step S20, the eccentricity correction step S30, the eccentricity inspection step S40, and the treating step S50 may be performed in the order of time series.

In the preparation step S10, the substrate W is taken into an inner space of the process chamber 300 and mounted on the support unit 330. More specifically, a transfer hand 246 seats the substrate W to be treated in the treating step S50 described later on the chuck 331. In this case, as described above, the top end of the treating container 320 is positioned lower than the top end of the chuck 331. If the substrate W is mounted on the top surface of the chuck 331, the eccentricity measurement step S20 is performed.

In the eccentricity measurement step S20, the eccentricity of the substrate W mounted on the chuck 331 is measured. More specifically, in the eccentricity measurement step S20, it is checked (confirmed) whether the center of the substrate W to be treated matches the center C of the chuck 331.

If the substrate W is mounted on the chuck 331, the first correction part 410 and the second correction part 440 move the substrate W to a reference position. The reference position according to an embodiment may be a position at which the center of the substrate W to be treated and the center of the chuck 331 match within an error range. The error range according to an embodiment may have a range of several micrometers. For example, the error range may be less than 20 micrometers. However, this is only for convenience of understanding, and a boundary of the inventive concept is not limited to the above-described error range.

An information on the center of the substrate W to be treated may be previously stored in a controller (not shown). For example, the information on the center of the substrate W to be treated can be individually stored in the controller (not shown) in a process of performing a pre-processing on each substrate such as a preceding substrate and a following substrate. The inventive concept is not limited thereto, and the information on the center of the substrates W stored in each container F may be individually stored for each container F. In addition, a coordinate information on the center C of the chuck 331 may be previously stored in the controller (not shown).

More specifically, the 1-1 contact part 422 and the 1-2 contact part 432 contact the first point and the second point on the side end of the substrate W sharing the X-axis on the horizontal plane, respectively. For example, both the 1-1 contact part 422 and the 1-2 contact part 432 move in a direction parallel to the first direction 2 and contact the substrate W. In addition, the 1-1 contact part 422 and the 1-2 contact part 432 move in a direction toward the substrate W, respectively. In other words, the 1-1 contact part 422 and the 1-2 contact part 432 move in opposite directions on the horizontal plane and contact the side end of the substrate W to move the substrate W to the reference position. That is, the 1-1 contact part 422 and the 1-2 contact part 432 may determine coordinates on the X-axis of the substrate W to be treated.

In addition, the second contact unit 441 moves on the Y-axis on the horizontal plane and contacts the third point on the side end of the substrate W. For example, the second contact unit 441 moves in a direction parallel to the second direction 4 and contacts the side end of the substrate W to move the substrate W to the reference position. That is, the second contact unit 441 may determine coordinates on the Y-axis of the substrate W to be treated.

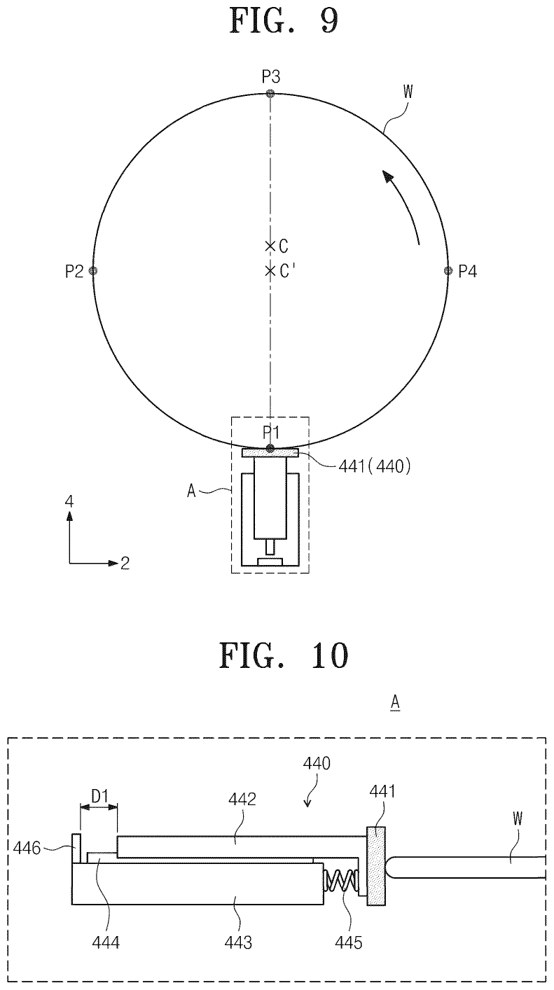

If the 1-1 correction unit 420, the 1-2 correction unit 430, and the second correction part 440 move the substrate W to the reference position, the chuck 331 rotates the substrate W. In addition, after moving the substrate W to the reference position, the position of the second contact unit 441 is not changed by the second driving unit 442. That is, after moving the substrate W to the reference position, the second driving unit 442 stops driving until the eccentricity measurement step S20 is completed. In FIG. 9, the substrate W rotates counterclockwise for example, but the substrate W may rotate clockwise.

In addition, while the substrate W rotates, the second correction part 440 measures the displacement of the second driving unit 442 for a plurality of points on the side end of the substrate W. According to an embodiment, while the substrate W is rotating, the second correction part 440 measures the displacement of the second driving unit 442 with respect to a first measurement point P1, a second measurement point P2, a third measurement point P3, and a fourth measurement point P4 on the side end of the substrate W. For example, the first measurement point P1, the second measurement point P2, the third measurement point P3, and the fourth measurement point P4 may be disposed at 90 degrees intervals based on the center of the substrate W.

Hereinafter, a mechanism for measuring the displacement of the second driving unit 442 and measuring the eccentricity of the substrate W accordingly will be described using specific figures. However, this is merely an example for the convenience of understanding.

If the center C′ of the substrate W to be treated matches the center C of the chuck 331 within the error range (hereinafter referred to as a normal state), the displacement values for multiple points measured by the displacement measurement part 446 all have constant values. For example, displacement values for a plurality of points measured by the displacement measurement part 446 in a normal state may be 50 micrometers.

However, as illustrated in FIG. 9, the center C′ of the substrate W to be treated at the reference position may be spaced apart from the center C of the chuck 331. For example, the center C′ of the substrate W to be treated and the center C of the chuck 331 may have the same X coordinates on the horizontal plane, but may have different Y coordinates. For example, the center C′ of the substrate W to be treated may be positioned a certain distance below the center C of the chuck 331.

As described above, the second driving unit 442 continuously contacts a plurality of points on the side end of the substrate W without being driven. The elastic part 445 is pressurized because the side end of the substrate W protrudes further from the first measurement point P1 toward the second contact unit 441, compared to the normal state shown in FIG. 10. Accordingly, the second driving unit 442 and the second contact unit 441 are pushed in a direction opposite to the substrate W by the elastic force of the elastic part 445. As a result, a displacement value D1 of the second driving unit 442 measured by the displacement measurement part 446 at the first measurement point P1 decreases compared to the normal state. For example, the displacement value D1 of the second driving unit 442 at the first measurement point P1 may be 10 micrometers. That is, at the first measurement point P1, a displacement difference of 40 micrometers occurs compared to the normal state.

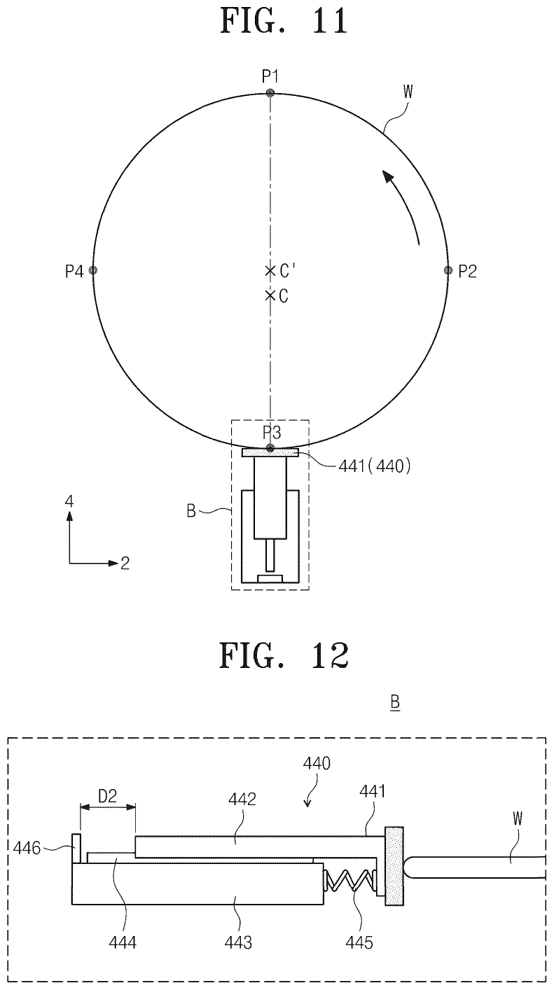

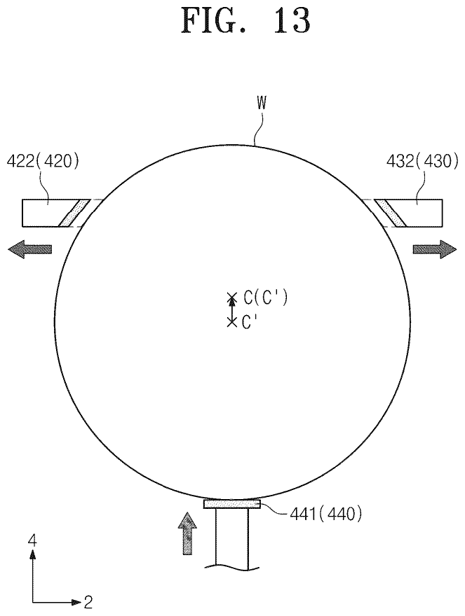

Subsequently, as shown in FIG. 11 and FIG. 12, the second contact unit 441 measures a displacement value D2 of the second driving unit 442 with respect to the third measurement point P3. Since the side end of the substrate W protrudes more in the direction of the second contact 441 than the third measurement point P3, the elastic part 445 is tensile. Accordingly, positions of the second driving unit 442 and the second contact unit 441 are restored in a direction toward the substrate W by the elastic force of the elastic part 445. As a result, the displacement value D2 of the second driving unit 442 measured by the displacement measurement part 446 at the third measurement point P3 increases compared to the normal state. For example, the displacement value D2 of the second driving unit 442 at the third measurement point P3 may be 90 micrometers. That is, at the third measurement point P3, a displacement difference of 40 micrometers occurs compared to the normal state.

The displacement value of the second driving unit 442 with respect to the plurality of points on the side end of the substrate W is measured by the same mechanism as in the above-described example. The controller (not shown) measures the eccentricity of the substrate W based on a plurality of measured displacement value information for each point which is measured. For example, if a displacement difference of 40 micrometers occurs compared to a normal state at the first measurement point P1, and a displacement difference of 40 micrometers occurs compared to a normal state at the third measurement point P3, the center C′ of the substrate W to be treated can be determined to be biased 20 micrometers downwardly from the center of the chuck on the Y-axis.

As described above, if the center C′ of the substrate W to be treated is positioned 20 micrometers apart from the center C of the chuck 331, it is determined that the substrate W to be treated has the eccentricity, and a subsequent eccentricity correction step S30 may be performed.

Unlike the above, if the center C′ of the substrate W to be treated is positioned 5 micrometers apart from the center C of the chuck 331, it is determined that the distance between the center C′ of the substrate W to be treated and the center C of the chuck 331 is within an error range. In this case, it is determined that there is no eccentricity in the substrate W to be treated, and a subsequent treating step S50 may be performed. Hereinafter, a case at which it is determined that an eccentricity exists in the substrate W will be described as an example.

If it is determined that an eccentricity exists in the substrate W, the eccentricity correction step S30 is performed. In the eccentricity correction step S30, the eccentricity of the substrate W is corrected. More specifically, in the eccentricity correction step S30, the position of the substrate W is changed according to a degree of eccentricity of the substrate W measured in the eccentricity measurement step S20, so that the center C′ of the substrate W is matched with the center C of the chuck 331 within an error range.

In the eccentricity correction step S30, the positions of the substrate W on the X-axis and/or Y-axis are changed. In the eccentricity correction step S30 according to an embodiment, the 1-1 correction unit 420 and the 1-2 correction unit 430 determine the position of the substrate W on the X-axis and on the Y-axis.

For example, if the center of the substrate W to be treated is eccentric only on the X-axis from the center of the chuck 331, the 1-1 correction unit 420 and the 1-2 correction unit 430 move in the same direction on the X-axis. Accordingly, the 1-1 contact part 422 and the 1-2 contact part 432 are in contact with the first point and second point on the side end of the substrate W, respectively, to change the position of the substrate W on the X-axis. Accordingly, the center of the substrate W and the center of the chuck 331 may be matched within an error range.

On the other hand, if the center of the substrate W to be treated is eccentric in both the X-axis and the Y-axis from the center of the chuck 331, the 1-1 correction unit 420 and the 1-2 correction unit 430 move in the same direction on the X-axis to firstly match the X-coordinate of the substrate W and the X-coordinate of the center of the chuck 331 within the error range. Subsequently, in order to match the Y coordinate of the center of the substrate W and the Y coordinate of the center of the chuck 331 within the error range, the 1-1 correction unit 420 and the 1-2 correction unit 430 may move in opposite directions. For example, if the center of the substrate W has to upwardly move on the horizontal plane, the 1-1 correction unit 420 and the 1-2 correction unit 430 move away from each other. On the contrary, if the center of the substrate W downwardly moves on the horizontal plane, the 1-1 correction unit 420 and the 1-2 correction unit 430 move in a direction closer to each other. In other words, the 1-1 correction unit 420 and the 1-2 correction unit 430 firstly correct the X coordinate of the center of the substrate W and then secondly move to a position at which the Y coordinate of the center of the substrate W is determined. Subsequently, the second correction part 440 contacts the side end of the substrate W to subsequently match the Y coordinate centered on the substrate W and the Y coordinate centered on the chuck 331 within the error range afterward. Accordingly, the center of the substrate W and the center of the chuck 331 may be matched within the error range.

On the other hand, if the center of the substrate W to be treated is eccentric only on the Y-axis from the center of the chuck 331, the 1-1 contact part 422 and the 1-2 contact part 432 may move only in opposite directions. For example, as described in FIG. 13, if the center C′ of the substrate W to be treated is spaced apart 20 micrometers in a downward direction from the center C of the chuck 331 on the horizontal plane, the 1-1 correction unit 420 and the 1-2 correction unit 430 move away from each other. If the 1-1 correction unit 420 and 1-2 correction unit 430 contact the side of the substrate W, the Y coordinate on the center of the substrate W to be treated moves to a position which matches the Y coordinate on the center of the chuck 331 within an error range. Subsequently, the second correction part 440 contacts the side end of the substrate W to upwardly move the substrate W by 20 micrometers. Accordingly, the center of the substrate W and the center of the chuck 331 may be matched within the error range to correct the eccentricity of the substrate W.

After correcting the eccentricity of the substrate W in the eccentricity correction step S30, the eccentricity inspection step S40 is additionally performed. In the eccentricity inspection step S40, it is examined whether the center of the substrate W to be treated matches the center of the chuck 331 within the error range. If the center of the substrate W is spaced apart from the center of the chuck 331 outside the error range, the eccentricity correction step S30 is performed again. Conversely, if the center of the substrate W is within the error range with the center of the chuck 331, a subsequent treating step S50 is performed. The eccentricity inspection step S40 is mostly the same or similar mechanism as the eccentricity measurement step S20, and measures the eccentricity of the substrate W to be treated, so a redundant description thereof will be omitted below.

In the treating step S50, a predetermined treatment is performed on the substrate W. More specifically, in the treating step S50, the edge region of the substrate W may be etched. During the treating step S50, the top end of the treating container 320 may be positioned higher than the top end of the substrate W supported by the chuck 331, as described above. For example, the nozzle 342 shown in FIG. 2 may supply an etching obstruction liquid to a central region of the rotating substrate W. The etching obstruction liquid supplied to the substrate W is diffused to the entire region of the substrate W by a centrifugal force, and a liquid film may be formed on the substrate W. Subsequently, the nozzle 342 supplies the etchant to the edge region of the substrate W. Accordingly, the edge region of the substrate W may be etched by the etchant.

The edge region of the substrate W may be precisely etched only if the substrate W is mounted at a correct position of the support unit 330. According to an embodiment of the inventive concept, the position of the substrate W can be accurately corrected even if the center of the substrate W is not accurately mounted on the center of the chuck 331.

Each substrate may have a slightly different size. According to the above-described embodiment, a dummy substrate may be used to accurately correct the position of each substrate to be treated individually without comprehensively correcting the position of individual substrates. In addition, after the 1-1 correction unit 420 and 1-2 correction unit 430 first determine the position of the X coordinate and/or Y coordinate centered on the substrate and correct it, the second correction part 440 subsequently corrects the Y coordinate of the substrate W more accurately.

Unlike the above-described example, in the substrate treating method according to an embodiment, the eccentricity inspection step S40 may be omitted. In addition, the process of etching the edge region of the substrate W was described as an example in the treating step S50, but it is not limited to this. For example, in the treating step S50, various processes using liquids can be performed, such as a coating process of forming a coating film on a surface of the substrate by supplying a photoresist to the substrate.

Hereinafter, an eccentricity correction unit according to another embodiment of the inventive concept will be described. The eccentricity correction unit described below is mostly the same as or similar to the configuration of the eccentricity correction unit described above, except for the case of additional description. Accordingly, a redundant description thereof will be omitted.

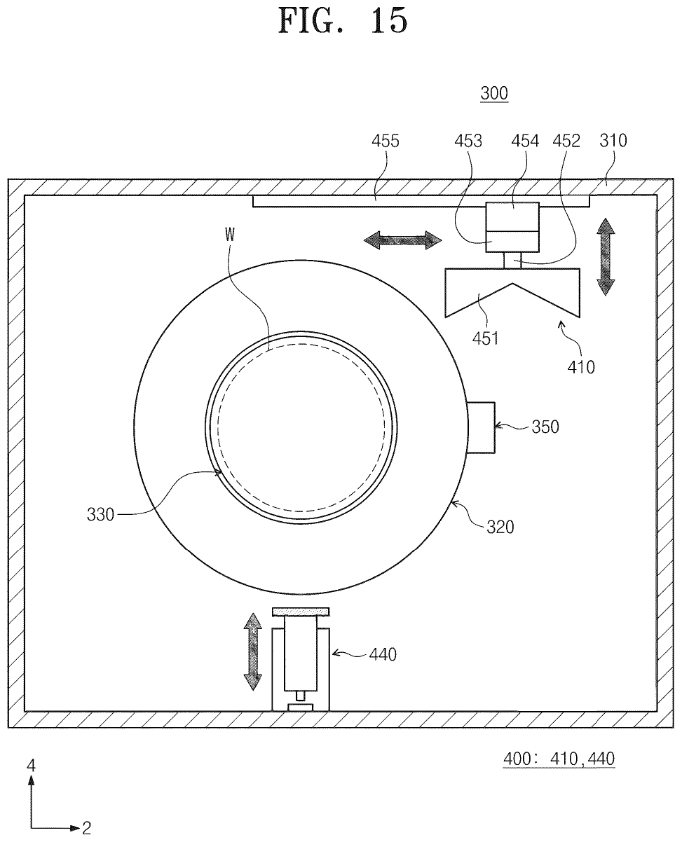

FIG. 15 is a cross-sectional view of the eccentricity correction unit installed in a process chamber according to another embodiment.

The first correction part 410 may include a first contact unit 451, a first arm 452, first driving units 453 and 454, and a first rail 455.

Since the first arm 452 has the same or similar structure as the first arm 424 described above, and the first rail 455 has the same or similar structure as the first rail 428 described above, a description thereof will be omitted.

The first contact unit 451 contacts a plurality of points on the side end of the substrate W to change the position of the substrate W. More specifically, the first contact unit 451 is in contact with two points on the side end of the substrate W. A surface of the first contact unit 451 may have a substantially ‘V’ shape when viewed from above. A surface of the “V” shape of the first contact unit 451 may be a surface in contact with the substrate W. In addition, a surface of the first contact unit 451 is made of the same material as a carbon-filled PEEK, so when contacting the substrate W, an impact on the substrate W can be minimized.

The first driving units 453 and 454 may move the first contact unit 451 in the first direction 2 and the second direction 4. The first driving units 453 and 454 may include a plurality of motors. Any one of the first driving units 453 and 454 moves the first contact unit 451 in a direction parallel to the first direction 2, and any one of the first driving units 453 and 454 moves the first contact unit 451 in a direction parallel to the second direction 4.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a chuck supporting a substrate;
a liquid supply unit configured to supply a liquid to a substrate supported on the chuck;
a treating container surrounding the substrate supported on the chuck; and
an eccentricity correction unit configured to correct an eccentricity of the substrate supported on the chuck, and
wherein the eccentricity correction unit contacts a plurality of points on a side end of the substrate supported on the chuck to match a center of the substrate with a center of the chuck.

2. The substrate treating apparatus of claim 1, wherein the eccentricity correction unit includes:
a first correction part configured to contact each of a first point and a second point among the points, sharing any one axis on a horizontal plane; and
a second correction part configured to contact a third point included in another axis which is different from the any one axis.

3. The substrate treating apparatus of claim 2, wherein the first correction part includes a 1-1 correction unit and a 1-2 correction unit, and
wherein the 1-1 correction unit includes:
a 1-1 contact part configured to contact the first point; and
a 1-1 driving unit configured to change a position of the 1-1 contact part, and
wherein the 1-2 correction unit includes:
a 1-2 contact part configured to contact the second point; and
a 1-2 driving unit configured to change a position of the 1-2 contact part.

4. The substrate treating apparatus of claim 3, wherein the 1-1 driving unit and the 1-2 driving unit move the 1-1 contact part and the 1-2 contact part, respectively, on the axis including the first point and the second point.

5. The substrate treating apparatus of claim 4, wherein the second correction part moves on an axis which is perpendicular to the axis on which the 1-1 contact part and the 1-2 contact part moves at a horizontal plane.

6. The substrate treating apparatus of claim 2, wherein the second correction part includes:
a second contact unit configured to contact the third point;
a second driving unit configured to change a position of the second contact unit; and
an elastic part configured to provide an elastic force in a moving direction of the second contact unit.

7. The substrate treating apparatus of claim 6, wherein the second driving unit moves along a guide rail formed on a top surface of a body,
the second contact unit is coupled to a surface of the second driving unit,
an other surface of the second driving unit facing the surface faces the body,
an end of the elastic part is coupled to the other surface, and
an other end of the elastic part is coupled the body facing the other surface.

8. The substrate treating apparatus of claim 7, wherein the second correction part further includes a displacement measurement part configured to measure a eccentricity of the substrate based on a displacement of the second driving unit by the elastic force of the elastic part.

9. The substrate treating apparatus of claim 8, wherein the displacement measurement part measures the displacement of the second driving unit with respect to different points of the substrate by rotating the chuck while the second contact unit is supporting the side end of the substrate, in a state in which the second driving unit is not driven.

10. The substrate treating apparatus of claim 1 further comprising a housing having an inner space, and
wherein the eccentricity correction unit is installed at a sidewall of the housing.

11. The substrate treating apparatus of claim 2, wherein the first correction part moves in a direction parallel to the any one axis, and moves in a direction perpendicular to the any one axis on a horizontal plane, and
the second correction part moves in a direction perpendicular to the any one axis at the horizontal surface

12.-19. (canceled)

20. A substrate treating apparatus comprising:
a housing having an inner space;
a chuck positioned in the inner space and supporting and rotating a substrate;
a liquid supply unit configured to supply a liquid to a substrate supported on the chuck to etch an etch region of the substrate;
a treating container surrounding the substrate supported on the chuck;
a lifting/lowering unit configured to lift and lower the treating container; and
an eccentricity correction unit configured to contact a plurality of points among a side end of the substrate supported on the chuck, to correct an eccentricity of the substrate supported on the chuck, and
wherein the eccentricity correction unit includes:
a first correction part configured to contact each of any one point and any other point among the points, sharing any one axis on a horizontal plane; and
a second correction part configured to another point included in an axis different from the any one axis, and
wherein the second correction part includes:
a displacement measurement part configured to measure a displacement degree with respect to different points of a rotating substrate; and
an elastic part configured to provide an elastic force by contacting the side end of the substrate.
